(19) United States
(12) Patent Application Publication
(10) Pub. No.: US 2009/0181476 A1
(43) Pub. Date: Jul. 16, 2009

(54) Assembly Method For Reworkable Chip Stacking With Conductive Film

(75) Inventors: Stephen L. Buchwalter, Hopewell Junction, NY (US); Bing Dang, Chappaqua, NY (US); Claudius Feger, Poughkeepsie, NY (US); Peter A. Gruber, Mohegan Lake, NY (US); John Knickerbocker, Monroe, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/972,129

(22) Filed: Jan. 10, 2008

(51) Int. Cl. H01L 21/02

(52) U.S. Cl. 438/15; 257/E21.531

(57) ABSTRACT

A method of stacking a chip, including an integrated circuit, onto a substrate including applying an anisotropic conductive film (ACF) or a solder-filled conductive film onto a surface thereof, the surface being configured to electrically couple to the film, placing the chip onto the film, the chip being configured to electrically couple to the film, compressively pressurizing the chip, the film and the surface such that the chip is electrically coupled to the surface via the film,, testing the chip to determine whether the chip is operating normally, reworking the placement of the chip onto the film and repeating the compressive pressurization if the chip is determined to not be operating normally, repeating the testing to determine whether the chip is operating normally, and once the chip is determined to be operating normally, bonding the chip, the film and the surface.

### BACKGROUND OF THE INVENTION

1. Field of the Invention

Aspects of the present invention are directed to a method of chip stacking and, more particularly, a method of chip stacking using an anisotropic conductive film (ACF) or a conductive film with solder-fillings.

2. Description of the Background

In conventional chip stacks, various metallurgical bonding methods have been employed. These methods include making use of Cu—Cu bonds, solder bump based bonds, and/or inter-metallic bonds. It has been found, however, that regardless of the method employed, the conventional methods have shortcomings that arise from their use.

For example, it has been found that encapsulation of the chip stacks is a challenge. That is, since wafer-level three-dimensional (3D) stacks need to be diced, during the dicing processes dust and moisture can be trapped in gaps between chips.

As additional examples, it has also been found that conventional chip stacking methods lack versatility and may not allow for low-cost assembly or reworkability. That is, once a chip stack is built, if the chip stack is found to not operate normally, correction of any problems in the chip stack may be difficult.

### SUMMARY OF THE INVENTION

In accordance with an aspect of the invention, a method of stacking a chip, including an integrated circuit (IC), onto a substrate is provided and includes applying an anisotropic conductive film (ACF) onto a surface of the substrate, the surface being configured to electrically couple to the ACF, placing the chip onto the ACF, the chip being configured to electrically couple to the ACF, compressively pressurizing the chip, the ACF and the surface in a direction that is normal to a plane of the surface such that the chip is electrically coupled to the surface via the ACF and such that a direction of the electric coupling is parallel to the direction of the compressive pressurization from the surface, through the ACF and to the chip, testing the chip to determine whether the chip is operating normally, reworking the placement of the chip onto the ACF and repeating the compressive pressurization if the chip is determined to not be operating normally, repeating the testing to determine whether the chip is operating normally, and once the chip is determined to be operating normally, bonding the chip to the ACF and bonding the ACF to the surface by an application of pressure and heat thereto.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTIONS OF THE DRAWINGS

The subject matter regarded as the invention is particularly pointed out and distinctly claimed in the claims at the conclusion of the specification. The foregoing and other aspects, features, and advantages of the invention are apparent from the following detailed description taken in conjunction with the accompanying drawings in which:

FIG. 1 is a flow diagram illustrating a method of stacking a chip according to an exemplary embodiment of the present invention.

FIG. 2 is an elevational view of a chip stacked onto an anisotropic conductive film and a substrate according to an exemplary embodiment of the invention;

FIG. 3 is an elevational view of a set of chips stacked onto a set of anisotropic conductive films and a substrate according to an exemplary embodiment of the invention;

FIG. 4 is a perspective view of a set of chip stacks arrayed on a wafer according to an exemplary embodiment of the invention; and

FIG. 5 is an elevational view of a chip stacked onto an anisotropic conductive film that includes solder-fillings, and a substrate according to an exemplary embodiment of the invention.

### DETAILED DESCRIPTION OF THE INVENTION

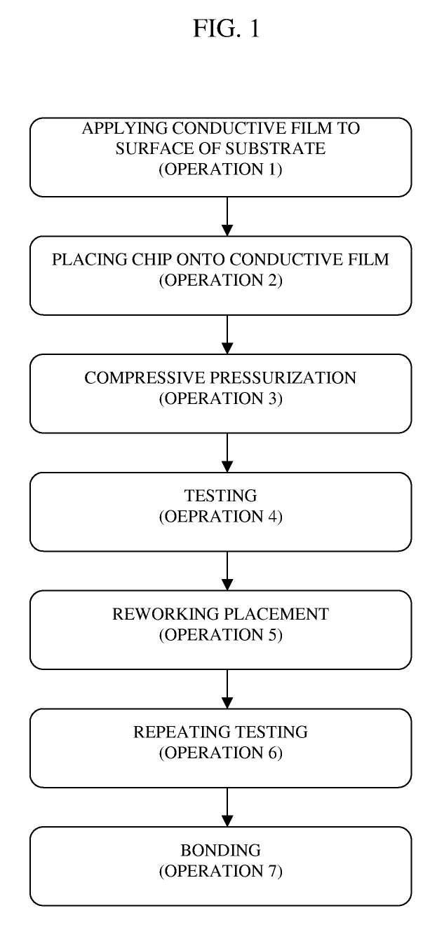

With reference to FIGS. 1-5, a method of stacking a chip 10, including an integrated circuit, onto a substrate 50 is provided and includes applying an anisotropic conductive film (ACF) 20 onto a surface 51 of the substrate 50 (operation 1), the surface 51 being configured to electrically couple to the ACF, placing the chip 10 onto the ACF 20 (operation 2), the chip 10 being configured to electrically couple to the ACF 20, compressively pressurizing the chip 10, the ACF 20 and the surface 51 in a direction that is normal to a plane of the surface 51 (operation 3) such that the chip 10 is electrically coupled to the ACF 20 and the ACF 20 is electrically coupled to the surface 51, testing the chip 10 to determine whether the chip 10 is operating normally (operation 4), reworking the placement of the chip 10 onto the ACF 20 and repeating the compressive pressurization (operation 5) if the chip 10 is determined to not be operating normally, repeating the testing to determine whether the chip 10 is operating normally (operation 6), and, once the chip 10 is determined to be operating normally, bonding the chip 10 to the ACF 20 and bonding the ACF 20 to the surface 51 (operation 7) by an application of pressure and heat thereto.

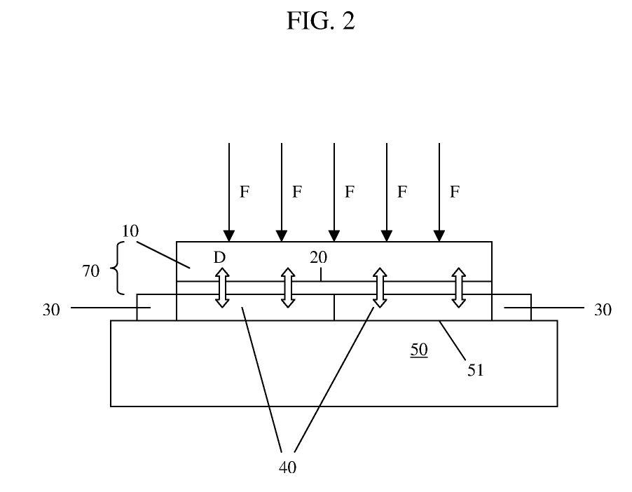

The chip 10, as shown in FIG. 2, 3 and 5, may include an integrated circuit (IC) and the surface 51 of the substrate 50 may include leads 30 and pads 40 arrayed thereon to allow the IC to control operations of a computer or machine in which the substrate 50 may be disposed. The chip 10 may, therefore, control operations of the computer or the machine via the pads 40 and the leads 30. Such control is accomplished via the ACF 20, which electrically couples the chip 10 to the pads 40 in only a direction, which is perpendicular to the plane of the surface 51. That is, the ACF 20 electrically couples the chip 10 to the pads 40 and the leads 30 in the direction, D, illustrated by the two-way arrows of FIGS. 2, 3 and 5.

In detail, as noted above, the ACF 20 electrically couples the chip 10 to the pads 40 and the leads 30 in only the direction, D, following the pressurization of the chip 10, the ACF 20 and the substrate 50 by the force, F, in operation 3 and as shown by the force arrows in FIGS. 2, 3 and 5. The ACF 20 comprises a composite material, such as a bulk polymeric material and conductive particles or metal-coated resin spheres. The conductive particles or spheres are loaded in the ACF 20 at a level below a percolation threshold, which is defined as the volume fraction at which a conductive path through the ACF 20 is defined by incidental particle-to-particle contact. Since the loading level of the conductive particles or spheres in the ACF 20 is below this threshold, no conductive path exists in either the x-y plane of the ACF 20 (i.e., into and out of the plane of the papers on which FIGS. 2, 3 and 5 are provided) nor in the direction, D, through the ACF 20.

Once a sufficient amount of compressive pressure is applied to the ACF 20 in the direction, D, the conductive particles or spheres are squeezed together and thereby form a conductive path only along the direction, D, and not in the x-y plane of the ACF 20.

In an alternate embodiment, the metal-coated spheres may have diameters that are slightly less than the thickness of the ACF 20. As such, compression in the direction, D, creates contacts from the chip 10 to the pads 40 but, since the spheres are loaded below the percolation threshold of the ACF 20, no conductive path is formed in the x-y plane of the ACF 20.

Once the chip 10 is electrically coupled to the ACF 20 and once the ACF 20 is electrically coupled to the pads 40 and the leads 30 of the surface 51, the normal operation of the chip 10 is tested, in operation 4, to insure that the chip 10 is electrically coupled to the pads 40 and the leads 30 and, therefore, operating normally. If the chip 10 is found to be operating normally, the bonding in operation 7 is commenced.

If the chip 10 is determined to not be operating normally, the placement of the chip 10 is reworked and the compressive pressurization of operation 3 is repeated in operation 5. Here, before the reworking of the chip 10 is undertaken, whether the ACF 20 needs to be replaced must be determined. The result of this determination depends upon the composition of the ACF 20. That is, if the ACF 20 comprises a thermoplastic, it may be reworkable by a disassembly process. Conversely, if the ACF 20 is cured, it may have to be replaced.

Once the chip 10 is reworked and the compressive pressurization is repeated, the testing of the chip 10 is also repeated to again determine if the chip is operating normally, in operation 6. At this point, if the chip 10 is found to be operating normally, the bonding of operation 7 is commenced or the reworking and compressive pressurization operations are repeated.

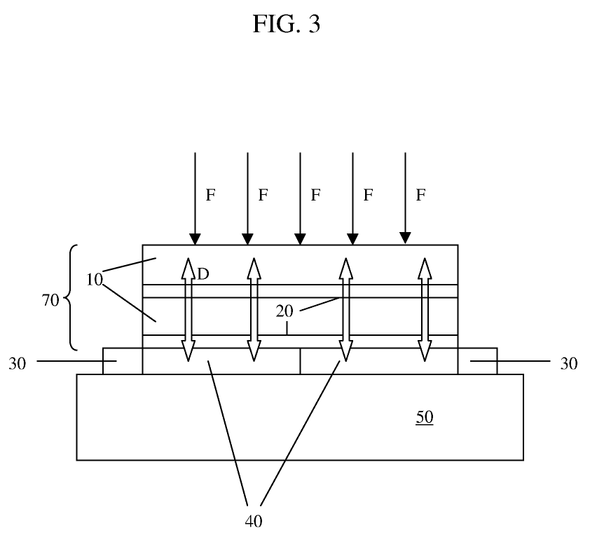

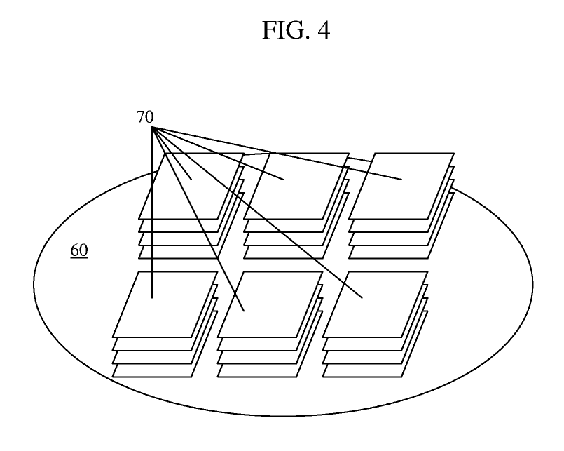

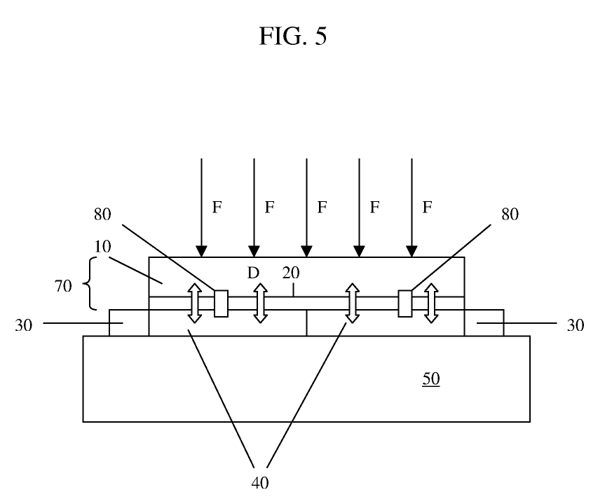

With particular reference to FIGS. 3 and 4, it is understood that, in an embodiment of the invention, the ACF 20 and the chip 10 may both be plural in number such that the applying of the ACF 20, in operation 1, and the placing of the chip 10, in operation 2, cooperatively result in a construction of a stack 70 of two or more ACFs 20 and the same number of chips 10. This is illustrated in FIG.3, in which a first ACF 20 is layered onto pads 40 a first chip 10 is placed on the first ACF 20, a second ACF 20 is layered on the first chip 10, and a second chip 10 is placed on the second ACF 20. Here, it is noted that a stack 70 could still refer to only a single chip 10 and a single ACF 20, as shown in FIGS. 2 and 5.

In accordance with this embodiment, the compressive pressurization of operation 3, the testing of operation 4, the reworking of operation 5, the repeating of the testing of operation 6, and the bonding of operation 7 are applied to the chip(s) 10 and the ACF(s) of the stack 70.

With reference to FIG. 4 and in accordance with a further embodiment of the invention, while the chip 10 and the ACF 20 may be singularly stacked or may be stacked as sets within a particular stack 70, the stack 70 may be plural in number. In this embodiment, a set of stacks 70 may be arrayed on the surface 51 of the substrate 50. Here, the substrate 50 may comprise a wafer 60 on which several docking areas for stacks 70 are provided. Once the stacks 70 are built, they may be separated from one another by dicing or other similar processes without substantial risk of moisture or dust entry.

With respect to the applying of the ACF 20 in operation 1, it is noted that the application of the ACF 20 may be accomplished via a lamination operation, in which the ACF 20 is pre-formed as a film and then laid on the appropriate surface, or a deposition and spinning operation, in which resin is deposited on the surface and the surface is spun at relatively high RPMs until the resin is formed into the film. This deposition and spinning operation may be particularly useful where the substrate is a wafer 60 and where the stacks 70 are plural in number. Here, the application of the ACF 20 for several stacks 70 may be accomplished simultaneously and efficiently.

With particular reference to FIG. 5, it is noted that, in another embodiment of the invention, the ACF 20 may comprise solder fillings 80. Such solder fillings 80 would be able to carry an amount of current, which is beyond a current carrying capacity of the ACF 20. As such, the solder filled ACF 20 could have applications beyond those ACFs 20 that are not equipped with solder fillings 80. In this embodiment, it is understood that the materials used for the ACF 20 and the solder fillings 80 must be chosen with their respective melting points considered so that, where reworking of a chip 10 is required, the ACF 20 can be heated and manipulated without disturbing placements of the solder fillings 80.

In accordance with another aspect of the invention, a chip stack includes a substrate 50 having a surface 51 on which leads 30 and pads 40 are arrayed, an anisotropic conductive film (ACF) 20 laid on the pads 40, and a chip 10, including an integrated circuit (IC), placed on top of the ACF 20 to be electrically coupled to the leads 30 via the ACF 20 and the pads 40 following a compressive pressurization for force, F, of the chip 10 and the ACF 20 in a direction, D, which is perpendicular to the plane of the surface 51. In accordance with this aspect of the invention, if, following the compressive pressurization, the chip 10 is found to not be operating normally, the chip 10 may be reworked and the compressive pressurization repeated. Once the chip 10 is found to be operating normally, the chip 10, the ACF 20 and the surface 51 are bonded together.

In accordance with yet another aspect of this invention, the method or its equivalents described above may be embodied as computer or machine readable media having executable instructions stored thereon to execute the method or its equivalents.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular exemplary embodiment disclosed as the best mode contemplated for carrying out this disclosure, but that the disclosure will include all embodiments falling within the scope of the appended claims.

We claim:

1. A method of stacking a chip, including an integrated circuit (IC), onto a substrate, the method comprising:
applying an anisotropic conductive film (ACF), including conductive particles that do not initially define a conductive path, onto a surface of the substrate, the surface being configured to electrically couple to the ACF;
placing the chip onto the ACF, the chip being configured to electrically couple to the ACF;
compressively pressurizing the chip, the ACF and the surface in a direction that is normal to a plane of the surface such that the conductive particles of the ACF form a set of discrete conductive paths from the chip to the surface via the ACF and such that a direction along which the discrete conductive paths extend is substantially parallel with that of the compressive pressurization;
testing the chip to determine whether the chip is operating normally;
reworking the placement of the chip onto the ACF and repeating the compressive pressurization if the chip is determined to not be operating normally;
repeating the testing to determine whether the chip is operating normally; and
once the chip is determined to be operating normally, bonding the chip to the ACF and bonding the ACF to the surface by an application of pressure and heat thereto.

2. The method according to claim 1, wherein the ACF and the chip are both plural in number such that the applying and the placing operations cooperatively result in a construction of a stack of ACFs and chips,
wherein the compressive pressurization operation, the testing, the reworking operation, the repeating of the testing and the bonding operations are applied to the stack, and
wherein the substrate comprises a wafer, and plural sets of the ACF and the chip or plural stacks of ACFs and chips are arrayed on the wafer.

3. The method according to claim 1, wherein the discrete conductive paths do not propagate in the planar direction of the ACF.

4. The method according to claim 1, wherein the application of the ACF comprises a lamination operation or a deposition and spinning operation.

5. The method according to claim 1, wherein the ACF comprises solder fillings to carry an amount of current, which is beyond a current carrying capacity of the ACF.
